(19) United States
(12) Patent Application Publication
(10) Pub. No.: US 2025/0060452 A1
(43) Pub. Date: Feb. 20, 2025

(54) RECEIVER

(71) Applicant: Novelda AS, Kviteseid (NO)

(72) Inventors: Sumit BAGGA, Kviteseid (NO); Nikolaj ANDERSEN, Kviteseid (NO)

(73) Assignee: Novelda AS, Kviteseid (NO)

(21) Appl. No.: 18/719,237

(22) PCT Filed: Dec. 13, 2022
(86) PCT No.: PCT/EP2022/085672

§ 371 Date: Jun. 12, 2024

(30) Foreign Application Priority Data
Dec. 13, 2021 (GB) 2118021.1

(51) Int. Cl. G01S 7/292; G01S 7/03; G01S 7/282; G01S 13/02

(52) U.S. Cl. CPC G01S 7/292; G01S 7/034; G01S 7/282; G01S 13/0209

(57) ABSTRACT

A transceiver circuit for transmitting and receiving via a single antenna interface, the transceiver circuit comprising: a transmitter arranged to send a transmit signal to the antenna interface; an amplifier arranged to receive a receive signal from the antenna interface; and a filter arranged between the antenna and the amplifier; wherein the transmitter circuit is arranged to source and/or sink current through an inductive element and wherein the inductive element is part of either the filter or the amplifier. This arrangement re-uses an inductive element that is already present within the circuit for other reasons (e.g., filtering, impedance matching, etc.). The inductive element may be any winding or coil. For example, it may be a stand-alone inductor, or it may be a transformer winding. Therefore, using an inductive element that is already present for other reasons saves area and in turn cost.

The invention relates to a receiver front-end, in particular it relates to a radio frequency (RF) front-end for a pulsed or impulse radar such as an ultra-wideband (UWB) radar.

UWB pulsed radars are often used for short range sensing such as proximity, presence and gesture detection, and heart rate and respiration monitoring. In such scenarios, the target to be detected can be very close to the radar, e.g., within a few centimeters, or even a few millimeters. A (strong) reflection from the target (or reflector) will then be received by the radar in a very short space of time after transmission, or even while transmission is still ongoing.

While a reflected signal from such a close target will still be very strong, the receiver architecture is designed for and must be capable of amplifying a reflection from significantly greater distance and therefore of much lower amplitude. The weak reflected signal is boosted by a high gain amplifier, typically a low-noise amplifier (LNA) and may also be accumulated over multiple individual pulses so as to reinforce the reflected signal while averaging out noise. A filter may be placed before the LNA to reject (unwanted) out-of-band signals.

The requirement for a high gain amplifier in the receiver hinders the design of the radar architecture in certain ways. In particular, the transmitter must be high powered to generate pulses with sufficiently large voltage swing so that reflections can be received from a required range. If those high power transmit pulses are fed to the amplifier of the receiver, they can damage the circuitry. Therefore, design is typically limited to either a two-port (2-port) full-duplex design (a transmitter driving a first antenna and a receiver amplifying signal from a second antenna) or a single-port (1-port) half-duplex design in which the receiver and transmitter share an antenna, but the receiver's amplifier is switched OFF or blocked during transmission to protect it from the high power transmit pulse. A 1-port transceiver design is beneficial in terms of form factor as each antenna can take up a lot of physical area. For example, where all the processing can be done on-chip, the antennae make up the majority of the overall device area. Therefore, removing one antenna can almost halve the device area (particularly important for incorporation into small and/or portable devices such as laptops, tablets, mobile telephones or wearable devices or other devices where space is constrained, e.g., the bezel around a display screen). However half-duplex operation restricts near-zero range detection as no reflections can be received (in the receiver's high gain mode) until after the transmitter has finished transmitting and the receive path has been switched back ON.

According to the invention there is provided a transceiver circuit for transmitting and receiving via a single antenna interface, the transceiver circuit comprising:
a transmitter arranged to send a transmit signal to the antenna interface;
an amplifier arranged to receive a receive signal from the antenna interface; and
a filter arranged between the antenna and the amplifier;
wherein the transmitter circuit is arranged to source and/or sink current through an inductive element and wherein the inductive element is part of either the filter or the amplifier.

Where a transceiver is designed for half-duplex operation via a single antenna interface, each of the transmitter and the amplifier are normally selectively connected to the antenna, i.e., each of them is connected via a switch that can be switched ON to connect to the antenna or switched OFF to disconnect from the antenna. In operation, either the transmitter or the amplifier (but not both) is connected at any given time. Thus, in such half-duplex transceivers, the components of the amplifier are always separated from the transmitter.

Filtering in such half-duplex transceivers is often done by antenna design such that the antenna acts as the filter, limiting received signals only to a particular band of interest. Where a separate filter is provided, this is normally an off-chip filter so as to use high Q components for optimal filtering with very low insertion loss.

Therefore, in half-duplex transceivers, the transmitter is normally powered separately from the other components, i.e., it sources and sinks current through its own dedicated connection to the supply rails.

The arrangement according to the invention re-uses an inductive element that is already present within the circuit for other reasons (e.g., filtering, impedance matching, etc.). The inductive element may be any winding or coil. For example, it may be a stand-alone inductor, or it may be a transformer winding. Monolithic inductors (or windings) are big body structures and expensive to produce, particularly on-chip where they typically require thick or ultra-thick metal layers in the fabrication process. Therefore, using an inductive element that is already present for other reasons saves area and in turn cost.

The inductive element may be connected to the supply rail or ground. If connected to the supply rail, the inductor allows the total signal swing to be higher than the supply voltage, e.g., between almost ground and up to almost twice the supply rail voltage, thereby allowing a much larger signal swing.

In order to implement a full-duplex or pseudo-full duplex transceiver, the receiver part of the circuit must be always-ON, i.e., capable of receiving while the transmitter is transmitting and while the transmitter is not transmitting. Pseudo-full-duplex here means simultaneous transmit and receive but with some compromise such as a reduced amplification of the receive signal. Such reductions in amplification are often tolerable, especially where the receive signal originates from a source near the antenna and provides a strong receive signal. This may be the case for example for a reflector close to the antenna in a pulsed radar system. However, when the receiver is always ON, it will remain ON while the transmitter is active. The transmitter needs to generate a pulse with a large signal swing in order for the transceiver to have an adequate range (i.e., for the transmitted signal to reach far from the antenna). With a single antenna shared between the transmitter and receiver, the receiver will receive the transmitted signal that is destined for the antenna, and it must therefore be able to withstand that signal strength without damage to itself and without damage to downstream components (particularly risky as such components will receive an amplified version of the strong transmit signal). The invention recognizes that with the receiver (i.e., the amplifier) always connected at the same time as the transmitter, inductive elements that form part of the amplifier may be available for re-use in order to sink or source current to the transmitter, thus saving components, area and cost.

The filter is normally a passive filter that does not require connection to the supply rail and is therefore also not typically considered a source of power (e.g., supply rail V_{dd}). However, the invention recognizes that such filters may be designed to sink unwanted signal to ground or the supply rail and can therefore be used as a connection to sink or supply current to the transmitter.

The filter is designed to be essentially transparent to the frequencies of interest (both transmit and receive), but it necessarily has finite insertion loss and will result in attenuation of any signal passing through it. The filter may be designed in any suitable way for a given implementation and use but is generally a high-pass or band-pass filter, optionally with one or more notches to exclude undesired interferers. The filter may be an LC-based filter comprising one or more inductors and any one of the inductors may be used as the inductive element that supplies or sinks current to/from the transmitter.

It will be appreciated that the arrangement described here is a direct-RF front end, i.e., the RF signal is received and processed directly without any frequency conversion. In such arrangements the filtering is particularly important to restrict the receive signal to just the signal of interest while excluding out-of-band interferers. In some cases, filtering can be achieved with just the antenna, but for direct-RF arrangements this is usually not sufficient and so a dedicated filter is required. By way of example only, in some direct-RF front ends the filter and amplifier try to realize around 60 dB attenuation out-of-band with a noise figure <5 dB.

The inductive element may be connected to a supply rail or to ground. It will be appreciated that the use of an inductor or an inductive element acts as a source or a sink for the current required by the active transmitter circuitry (e.g., transistors). It can also be used to bias said transistors.

The amplifier can take many different forms and many different arrangements. In some embodiments the amplifier is an impedance matching amplifier, and the inductive element is part of a transformer of the amplifier. In such amplifiers the transformer provides one gain mechanism of the amplifier by coupling signal across an amplifying element such as a transistor. Impedance matching of the amplifier is very important in order to avoid signal loss through the signal chain from antenna to processing circuitry and an impedance matching amplifier is designed to match its input impedance to that of the preceding components for minimal losses (i.e., minimal reflection).

It may be noted that the transformer here could be in a number of different arrangements. For example, it could be a bifilar transformer, a trifilar transformer or a multi-filament (e.g., quadrifilar) transformer, etc. More than one transformer may be present in the amplifier. In particular, in some embodiments two bifilar transformers may be used, e.g., one to couple signal from the output to the input and one to enhance the signal at the input and/or the output.

In some embodiments the amplifier comprises an impedance matching amplifier arranged to receive the receive signal from the antenna interface. The impedance matching amplifier provides transconductance gain (i.e., voltage to current conversion). The impedance matching amplifier can be designed so that the correct impedance match is one of its characteristics, while still providing gain to the input signal.

The impedance matching amplifier may comprise a transistor or multiple transistors arranged in a common-gate and/or a common-source arrangement. Both arrangements are equally viable and will be described further below. One way to achieve this is with a field effect transistor arranged in either common-gate or common-source configuration, with the windings of a trifilar transformer coupling the signal between at least the gate and the source, while ensuring that there is only coupling between two of its windings (which ensures stability and/or maximum gain). This arrangement allows additional characteristics, such as the turns ratio of the windings and the coupling coefficient to impact on the impedance matching. Therefore, the amplifier can be designed for both gain and impedance matching. While a trifilar arrangement is particularly convenient and area-efficient, a similar effect can also be achieved with a combination of two transformers (bifilars).

It will be appreciated that this amplifier will see the full power of the transmit signal when the transceiver is in transmit mode. Thus, this can be designed to be sufficiently robust to handle the large-signal swing from the transmitter. It will be appreciated that as this is the first amplifier in the receive path, it has not yet amplified the transmitter signal and so is the least problematic part of the receive path. The signal downstream of this amplifier (i.e., further from the antenna) has been amplified, and thus, becomes a reliability issue (i.e., risks damaging downstream components). This arrangement is of particular benefit in pulsed transceivers, e.g., pulsed, or impulse radars. In such systems (as opposed to continuous wave transceivers) the transmitter is only active for short periods of time (to transmit a pulse) before going inactive for long periods of time (the rest of the pulse repetition period). Thus, the power that must be withstood by the amplifier is short and transient and thus a sufficiently robust transistor can be incorporated without great expense. The arrangement is especially beneficial in low-power transceivers, e.g., UWB transceivers as the transmit power restrictions in the UWB band also facilitate the use of an amplifier element that is fully exposed to the full transmit power of the transmitter.

Note that the single common-gate or common-source transistor mentioned above can be replaced by multiple transistors acting as a transconductance stage. For example, the gain stage could be a circuit (commonly referred to as a Darlington pair) comprising two transistors with the source of the first transistor connected to the gate of the second transistor, and the drains of the two transistors connected. Another example being a common-source transistor and a common-gate transistor in parallel arrangement with the source of the common-gate transistor connected to the gate of the common-source transistor and with the drains of the two transistors connected via an ‘inversion’. Other multiple transistor arrangements are also possible.

The transceiver circuit may further comprise a DC blocking capacitor between the inductor and the control terminal of the transistor. As noted above, powering the transmitter through the inductor provides a DC path through the transmitter. However, it is desirable to separate that from the transistor of the amplifier and instead provide a more optimal bias voltage to the control terminal (e.g., the base or gate) of the transistor. The DC blocking capacitor provides this separation.

In some embodiments the impedance matching amplifier comprises a field effect transistor and the impedance matching amplifier further comprises a transformer coupling the signal between the gate and the source of the field effect transistor. Coupling between the gate and the source provides a feedback mechanism for coupling signal from the output to the input of the amplifier and thereby enhancing the gain of the transistor. The inductive element discussed above may be a winding of the transformer. Depending on the particular arrangement the winding at either the gate or the source may be used to power the transmitter.

In some embodiments the field effect transistor is in common-source arrangement and the amplifier comprises a transformer arranged to amplify the signal at the gate of the field effect transistor. This transformer may be the only transformer in the amplifier, or it may be in addition to the transformer coupling signal between the gate and the source. Alternatively, as noted above, a single transformer (a trifilar) may provide both functions.

Thus in some embodiments the transformer is a trifilar transformer with a primary winding connected to the source, a secondary winding connected between the gate and ground or signal ground (e.g. an AC ground) and a tertiary winding connected between the secondary winding and the gate, wherein the primary winding and the secondary winding are coupled in inverting relationship, wherein the secondary winding and the tertiary winding are coupled to increase voltage at the gate, and wherein there is substantially no coupling between the primary winding and the tertiary winding. With this arrangement, the coupling between the primary and secondary windings increases the gate-source voltage as discussed above, thereby providing one gain mechanism. At the same time, the coupling between the secondary and tertiary windings further increases the gate voltage (and therefore also the gate-source voltage), thereby providing an additional gain mechanism. At the same time, as the input impedance of the arrangement depends upon both the transconductance of the transistor and the turns ratios of the transformer, it is possible to achieve good impedance matching via a well-defined input impedance as well as high gain. More details of this type of arrangement can be found in WO2018/033743, the entire contents of which are incorporated herein by reference. A similar effect may be achieved by using two bifilar transformers instead of a trifilar. This may be achieved with one bifilar providing coupling between the source and the gate (equivalent to the primary and secondary of the trifilar), and one bifilar providing coupling to increase the gate voltage (equivalent to the secondary and tertiary of the trifilar).

Signal ground here means any ground to which the signal can be dissipated. This may be a positive or negative voltage rail, an AC ground, or any other ground connection of the circuit.

In other examples, the field effect transistor may be in common-gate arrangement and comprises a transformer coupling the signal between the source and the drain of the field effect transistor. This coupling provides an additional gain mechanism by applying the signal sensed at the drain to the source. By arranging the transformer in a non-inverting relationship, the drain-source current is increased, thereby increasing the gain of the transistor.

In such examples, the transformer may be a trifilar transformer with a primary winding connected to the source, a secondary winding connected to the gate and a tertiary winding connected to the drain, wherein the primary winding and the secondary winding are coupled in an inverting relationship and wherein the primary winding and the tertiary winding are coupled in non-inverting relationship, and wherein there is substantially no coupling between the secondary winding and the tertiary winding. With this arrangement, the coupling between the primary and secondary windings increases the gate-source voltage as discussed above, thereby providing one gain mechanism. At the same time, the coupling between the primary and tertiary windings increases the drain-source current, thereby providing an additional gain mechanism. At the same time, as the input impedance of the arrangement depends upon both the transconductance of the transistor and the turns ratios of the transformer, it is possible to achieve good impedance matching via a well-defined input impedance as well as high gain. More details of this type of arrangement can be found in WO2019/086853, the entire contents of which are incorporated herein by reference. A similar effect may be achieved by using two bifilar transformers instead of a trifilar. This may be achieved with one bifilar providing coupling between the source and the gate (equivalent to the primary and secondary of the trifilar), and one bifilar providing coupling between the source and the drain (equivalent to the primary and tertiary of the trifilar).

As noted above, the invention is particularly beneficial for duplex operation via a single antenna interface. Therefore, in some embodiments the transmitter is arranged to remain in signal communication with the amplifier during both transmit operation and non-transmit operation. Preferably, there is no (analog/RF) switch between the transmitter and the amplifier. Similarly, the amplifier is preferably arranged to remain in signal communication with the antenna during both transmit operation and non-transmit operation. Preferably, there is no switch between the antenna and the amplifier. As there are no switches to select or deselect (i.e., switch ON or OFF) either the transmitter or the amplifier (receiver), both remain operational all the time, i.e., both are always-ON for duplex operation. The absence of switches improves the signal path by avoiding the inevitable insertion loss associated with any switch in the signal path. Both the transmit path and the receive path can benefit from the absence of such switches. As the amplifier remains connected, it is biased and impedance matched during both signal transmission and reception.

In some embodiments the transmitter, amplifier and filter are all fabricated on the same chip. In other embodiments the filter may be off-chip. However, the invention is particularly beneficial when the filter is on-chip. Off chip filters have the benefit of having a very high Q factor and therefore a low insertion loss, but they require additional physical area outside the chip and add to the overall cost of the device. As discussed above, when both the filter and transmitter are on-chip, resource sharing can take place. An on-chip filter also keeps down the cost and size. Also, when the transmitter is always-ON (for duplex operation), there is no RF switch adding insertion loss and therefore the insertion loss of the on-chip filter is offset slightly.

The transmitter may be connected to any suitable point in the transceiver from which it can source and/or sink current. Where the transmitter is arranged to source and/or sink current from the filter, the transmitter may be connected to any node before, within, or after the filter, e.g., on either side of the filter or to a node within the filter, so long as that node is also connected through the inductive element to a current source or sink (e.g., via the supply rail or to ground). In some embodiments it is preferred that the inductive element is connected to a supply rail.

In some embodiments the transmitter is connected to a node between the filter and the amplifier. As signal strength of the transmitter is important for range, placing the transmitter between the antenna and the filter avoids attenuating the transmit signal that reaches the antenna while attenuating the transmit signal that reaches the receiver. This has traditionally been considered the optimum position for transmitter placement. However, it has now been recognized that when trying to design a circuit for full-duplex or pseudo-full-duplex operation, there are advantages to connecting the transmitter instead between the filter and the amplifier. When the transmitter is connected between the antenna and the filter, its OFF capacitance may degrade the impedance match. This is not a problem in half-duplex arrangements where the transmitter can be disconnected via an RF switch during receive mode operation so that the filter-antenna node does not see this unwanted capacitance in receive mode. However, when the transmitter is to be connected without an RF switch this becomes more of a problem. Insertion loss (i.e., adding to the noise figure of the receiver) is the main drawback of using an explicit RF switch for single port transceiver front-ends. Moving the transmitter to be connected between the filter and the amplifier allows the OFF capacitance of the transmitter to be absorbed in the impedance matching of the amplifier. The capacitance of the transmitter can effectively form part of the impedance matching network of the amplifier and as it is always-ON, there is no change to the impedance matching between transmit and non-transmit/receive modes. An additional advantage is that the filter can act to filter the outgoing transmit signal and therefore can be used to ensure spectrum compliance. Such spectrum compliance would otherwise need to be ensured in the transmitter itself, so re-using the filter (which is already required to filter the receive signal) results in overall reduced circuit area and therefore reduced cost.

While the above circuits have been described as single-ended, it will be appreciated that the circuit may be differential, i.e., with a differential antenna interface, a differential filter, a differential transmitter, and a differential amplifier. In such embodiments, the differential circuit comprises a first differential signal path and a second differential signal path, which may be considered as a positive path and a negative path, and each differential signal path is processed in the same way, i.e., the differential transmitter provides positive and negative transmit signals onto the two differential paths and the filter and amplifier are each arranged to filter and amplify respectively the signal received from the differential antenna on the two differential signal paths.

According to another aspect of the invention, there is provided a transceiver circuit for transmitting and receiving via a single antenna interface, the transceiver circuit comprising:
a transmitter arranged to send a transmit signal to the antenna interface;
an amplifier arranged to receive a receive signal from the antenna interface; and
a filter arranged between the antenna and the amplifier;
wherein the transmitter is connected to a node between the filter and the amplifier.

It will be appreciated that this aspect of the invention is closely related to all of the above features, with focus on the point of connection rather than the power supply arrangement. However, it will be appreciated that power may be supplied through an inductive element in the same way as described above. Thus, in some embodiments the transmitter circuit is arranged to source and/or sink current through an inductive element, wherein the inductive element is part of either the filter or the amplifier. Equally, all the other preferred and optional features discussed above are also applicable and may be applied to this aspect of the invention. Indeed both aspects of the invention may be embodied in the same circuits, including any or all of the optional features.

According to another aspect of the invention, there is provided a transceiver comprising: an antenna; and a transceiver circuit as discussed above (optionally including any of the preferred or optional features also discussed above). The transmitter may comprise an impulse or pulse generator.

According to another aspect of the invention, there is provided a pulsed radar comprising a transceiver as discussed above.

According to another aspect of the invention, there is provided a method of duplex operation of a transceiver circuit via a single antenna interface, wherein the transceiver circuit comprises:
a transmitter arranged to send a transmit signal to the antenna interface; and
an amplifier arranged to receive a receive signal from the antenna interface; and
a filter arranged between the antenna and the amplifier;
wherein the method comprises:
the transmitter transmitting a transmit signal by sourcing and/or sinking current through an inductive element. The inductive element may be part of either the filter or the amplifier.

According to another aspect of the invention, there is provided a method of duplex operation of a transceiver circuit via a single antenna interface, wherein the transceiver circuit comprises:
a transmitter arranged to send a transmit signal to the antenna interface; and
an amplifier arranged to receive a receive signal from the antenna interface; and
a filter arranged between the antenna and the amplifier;
wherein the method comprises:
the transmitter transmitting a transmit signal onto a node between the filter and the amplifier.

All of the preferred and optional features described above in relation to the apparatus may equally be applied in relation to either of these methods and therefore further description thereof is omitted here.

Certain preferred embodiments of the invention will now be described, by way of example only, and with reference to the accompanying drawings in which:

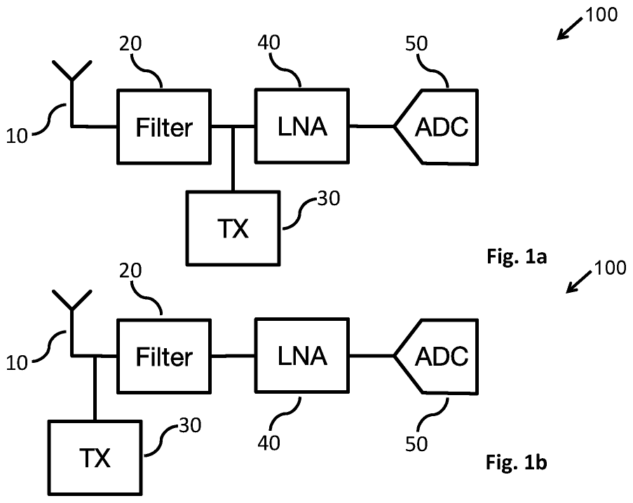

FIGS. 1a and 1b show two RF front-end topologies;

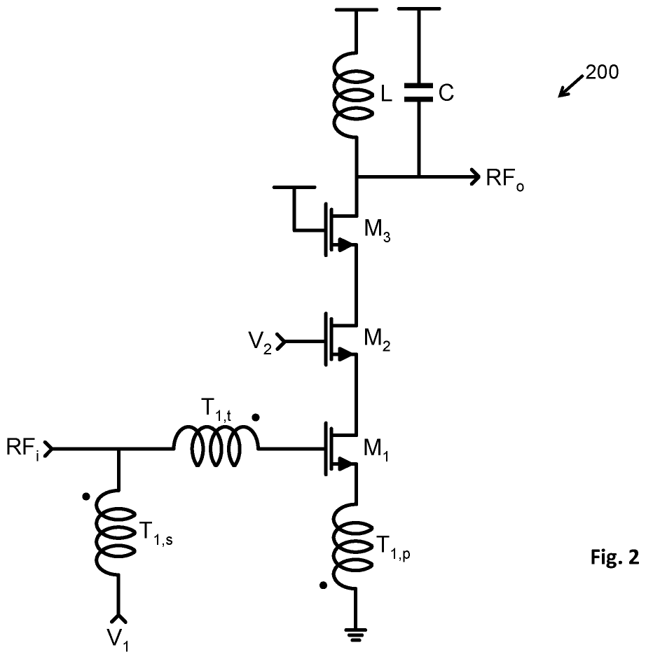

FIG. 2 shows a common-source low-noise amplifier arrangement for half-duplex operation;

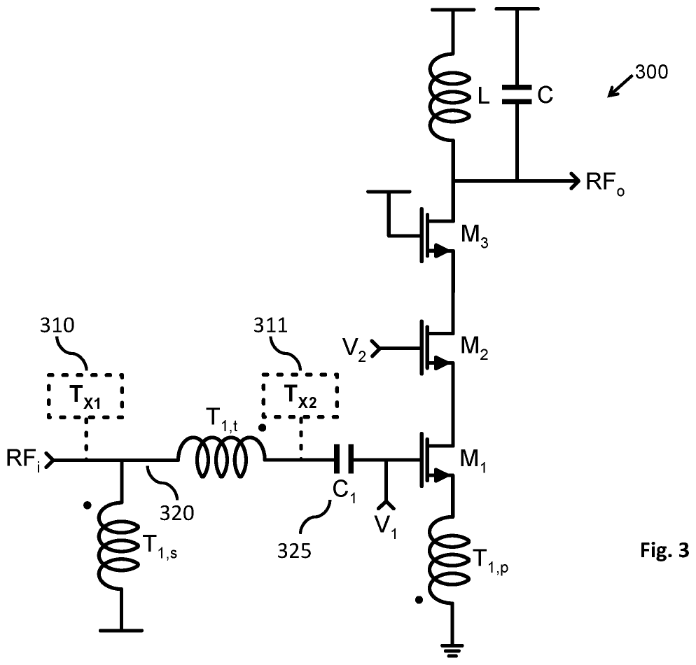

FIG. 3 shows an embodiment of the invention with two possible nodes at which to connect the transmitter in a common-source amplifier;

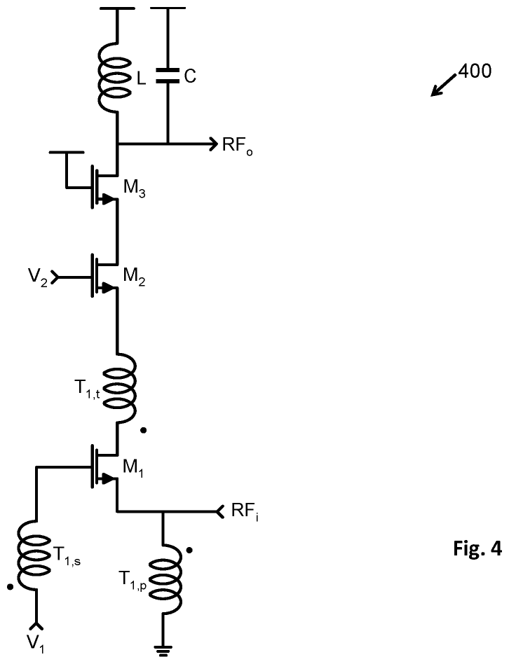

FIG. 4 shows a common-gate low-noise amplifier arrangement for half-duplex operation;

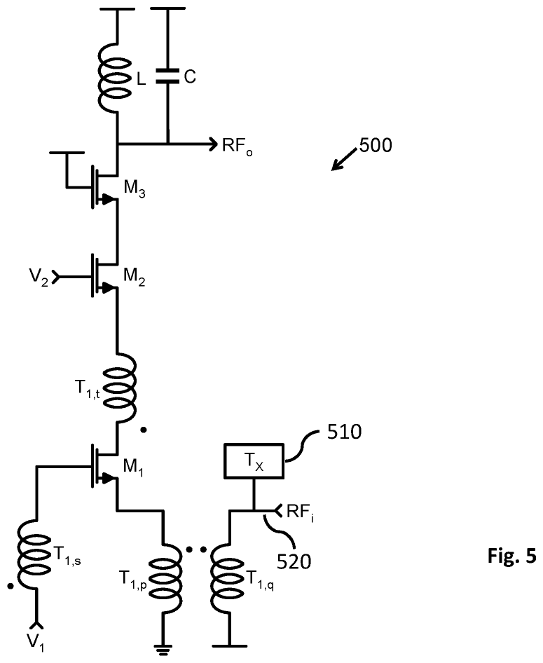

FIG. 5 shows an embodiment of the invention with one way of powering the transmitter in a common-gate amplifier with a multi-filament transformer;

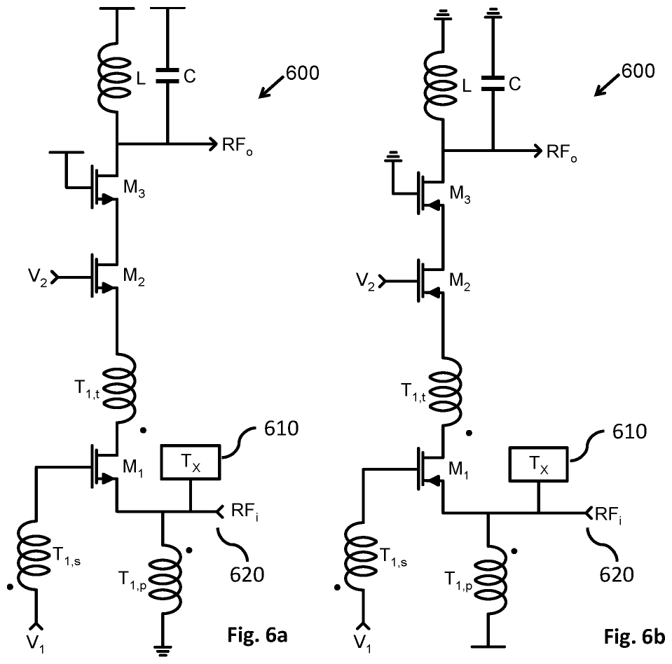

FIG. 6 shows another embodiment of the invention with another way of powering the transmitter in a common-gate amplifier with a trifilar and PMOS transistors;

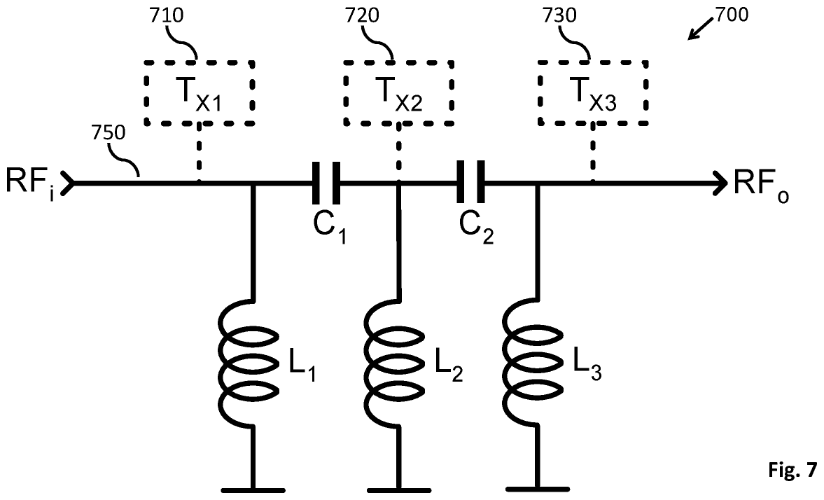

FIG. 7 shows the transmitter powered from a passive filter's transformer winding;

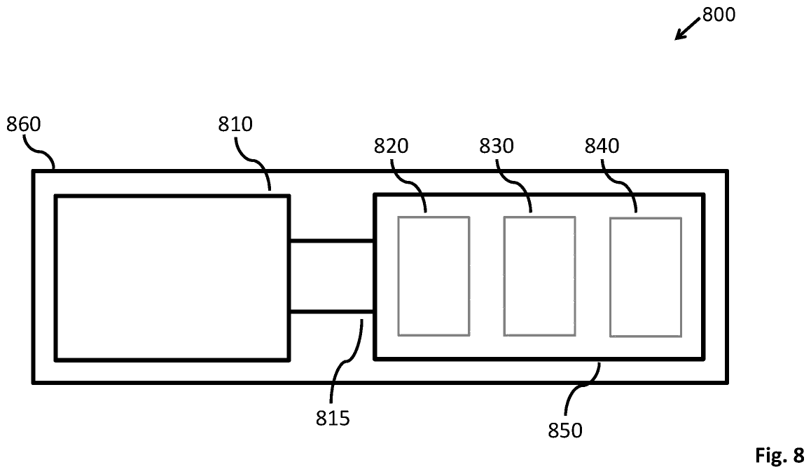

FIG. 8 shows schematically the components of a pulsed radar module.

FIGS. 1a and 1b show two different general arrangements for a direct radio frequency (RF) transceiver front-end 100. Both of these arrangements are single-port devices, i.e., they have a single antenna 10 that is used for both transmission and reception. Each front-end 100 has an antenna 10, a filter 20, a low-noise amplifier (LNA) 40, an analog-to-digital converter (ADC) 50 and a transmitter 30. As these are direct RF front ends there are no mixers for up/down conversion. FIG. 1a shows the arrangement according to some embodiments of the invention and shows the transmitter 30 connected to a node between the filter 20 and the LNA 40. FIG. 1b shows the transmitter 30 connected according to other embodiments of the invention where it is connected instead between the antenna 10 and the filter 20. One difference between these arrangements is in whether the output from the transmitter 30 gets filtered by the filter 20. The advantage of the arrangement in FIG. 1a is that the transmitter 30 signal is filtered by the filter 20. This helps to ensure that the transceiver output meets frequency transmission requirements. For example, for an UWB (ultra-wide band) transmitter, there is a spectrum mask that must be adhered to. Applying the filter 20 to the output of the transmitter 30 helps to filter out frequencies that would violate the spectrum mask. However, the filter 20 also results in a certain degree of attenuation. Ideally the filter 20 is transparent to the signals of interest (both outgoing and incoming), but in reality, there is always an insertion loss associated with any passive filter 20. Therefore, placement of the filter 20 as in FIG. 1a means that the transmitter 30 must be higher powered in order to make optimum use of the available spectrum mask (or alternatively, for a given power, the range of the device is compromised by the insertion loss in the filter 20). The full power of the transmitter 30 is also then seen by the receiver parts of the circuit, i.e., the LNA 40 and ADC 50. A higher-powered transmitter 30 can risk damaging these components and therefore placement of the transmitter 30 as in FIG. 1a means that care needs to be taken to ensure that the LNA 40 and ADC 50 are not damaged by the transmitter 30. With the arrangement of FIG. 1b the full power of the transmitter 30 is available to the antenna 10 without loss, but it is unfiltered, hence potentially compromising the spectrum efficiency of the transmitter 30 or requiring additional filtering to be built into the transmitter 30 or antenna. It will be appreciated that both of these arrangements (FIGS. 1a and 1b) have their own advantages and disadvantages, but the invention is applicable to both.

FIG. 2 shows the basic construction of a common-source amplifier 200 with a trifilar transformer for high gain and impedance matching. For maximum gain, the primary winding T_{1,p} is coupled to the secondary winding T_{1,s} and the secondary winding T_{1,s} is couple to the tertiary winding T_{1,t}. However, the tertiary winding T_{1,t} is not coupled to the primary winding T_{1,p} so as to ensure maximum gain of the amplifier. The turns ratios of T_{1,p} to T_{1,s} and T_{1,s} to T_{1,t} also affect the impedance matching of the amplifier and therefore both the gain and the impedance matching can be set as desired. The three windings T_{1,p}, T_{1,s} and T_{1,t}, together with the field effect transistor M₁ in common-source arrangement form the impedance matching amplifier. Stacked on top of that amplifier are two common-gate stages each comprising a field effect transistor M₂ or M₃ to increase the output impedance. The topmost common-gate stage transistor M₃ improves reverse isolation by providing a high output impedance and thereby isolating the load (represented by inductor L and capacitor C) from the common-source amplifier stage M₁. Note that both common-gate stages M₂ and M₃ are always-ON. These are not arranged to be switchable.

FIG. 3 shows the amplifier of FIG. 2 but showing the transmitter 310 connected to the antenna in accordance with embodiments of the invention. Although not shown in FIG. 3, the antenna is connected to the signal path 320 to the left, with a filter interposed between the antenna and the circuit of FIG. 3 (i.e., as shown in FIG. 1a). The signal path 320 carries the receive signal from the antenna through the filter and into the receiver as indicated by RFᵢ.

Two alternative transmitter placements are shown, labelled T_{X1} and T_{X2}, but it will be appreciated that only one of these is required (as indicated by the dashed lines).

The only difference between the two connection points T_{X1} and T_{X2} is that T_{X1} is connected upstream (i.e., towards the antenna) of the transformer winding T_{1,t}, while T_{X2} is connected downstream (i.e., further from the antenna) of the transformer winding T_{1,t}.

In both case (T_{X1} and T_{X2}), the transmitter 310 (or 311 for T_{X2}) is directly and continually connected to the signal path 320. There are no switches in the path from the transmitter 310 (or transmitter 311) to the signal path 320 that disconnect the transmitter 310 (or transmitter 311), so it is in an always-connected state. This does not mean that it is always transmitting, but it means that even when the transmitter 310 (or transmitter 311) is not generating a transmit signal, its “off-capacitance” is still present and affects the other components attached to the signal path 320.

The transmitter 310 is powered through the inductor T_{1,s}, which is in fact the secondary winding of trifilar transformer T₁. As is shown in FIG. 3, the winding T_{1,s} is connected between the supply rail, V_{dd}, and the signal path 320. Therefore, a DC current flows from the supply rail onto the signal path 320 and from there to the transmitter 310 which is in turn connected to ground (not shown). In order to prevent the voltage of the supply rail being applied to the gate of field effect transistor M₁, a DC blocking capacitor 325 is positioned between the connection point T_{X1} and the gate of M₁. In this example, the DC blocking capacitor 325 is also positioned between the connection point T_{X2} and the gate of M₁, so it is suitable for either configuration. However, it will be appreciated that the DC blocking capacitor 325 could instead be placed between the winding T_{1,t} and the connection point T_{X1}. In FIG. 2, the transistor M₁ was biased via the voltage V₁ provided through winding T_{1,s}. However, in FIG. 3, the winding T_{1,s} is now connected to V_{dd}. Therefore, in order to bias M₁ correctly, the bias voltage V₁ is now connected the other side of the DC blocking capacitor 325, i.e., it is connected to the signal path 320 between the DC blocking capacitor 325 and the gate of M₁.

The use of the transformer winding T_{1,s} to power the transmitter has two main benefits. One is that it allows the signal swing of the transmitter 310, 311 to be higher than the supply voltage, e.g., it can swing from almost ground up to almost 2*V_{dd}. This allows a much larger transmit signal to be produced for transmission.

The other advantage is that the winding T_{1,s} is already present as part of the impedance matching amplifier 300. Therefore, the transmitter has been powered without having to add another large and costly inductor to the circuit.

In addition, because the transmitter 310 is connected to the signal path 320 adjacent the amplifier 300, its capacitance (in particular its off-capacitance, i.e. the capacitance of the transmitter when it is not transmitting and all its internal switches are open, which will typically be higher than its on-capacitance when at least some of its internal switches are closed) can be taken into account in the impedance matching design of the amplifier 300. This arrangement was discussed above and is further set out in WO2018/033743. The trifilar transformer T₁ of the amplifier 300 defines both the input impedance of the amplifier 300 and its gain. The primary winding T_{1,p} is connected to the source, the secondary winding T_{1,s} is connected between the gate and V_{dd} (which acts as a signal ground) and the tertiary winding T_{1,t} is connected between the secondary winding T_{1,s} and the gate of M₁. The primary winding and the secondary winding are coupled in inverting relationship, while the secondary winding and the tertiary winding are coupled so as to increase the gate voltage of M₁. With the right design of trifilar transformer T₁, there can also be very low or substantially no coupling between the primary winding and the tertiary winding. The coupling between the primary T_{1,p} and secondary T_{1,s} windings increases the gate-source voltage of M₁, thereby providing one gain mechanism. The coupling between the secondary T_{1,s} and tertiary T_{1,t} windings further increases the gate voltage of M₁ (and therefore also the gate-source voltage of M₁), thereby providing an additional gain mechanism. At the same time, as the input impedance of the arrangement depends upon both the transconductance of the transistor M₁ and the turns ratios of the three windings of transformer T₁, it is possible to achieve good impedance matching via a well-defined input impedance as well as high gain. The capacitance of the transmitter 310 can be taken into account when selecting M₁ and the turns ratios of the windings T_{1,p}, T_{1,s} and T_{1,t} so that the amplifier remains properly matched for optimum signal transfer into the amplifier (minimal reflection). As the transmitter 310 is always-connected, the impedance matching of the amplifier 300 does not change between transmit and receive modes and therefore it continues to operate efficiently throughout both transmit and non-transmit operation, thereby allowing good full-duplex (or pseudo-full-duplex) operation.

With the transmitter 311 connected at T_{X2} rather than T_{X1}, the only difference is that the transmitter is powered (i.e. sources and/or sinks current) through both windings T_{1,s} and T_{1,t}. The functionality is otherwise the same. However, positioning the transmitter 311 in this location is less-desirable as the transmit signal gets scaled down by the transformer windings T_{1,s} and T_{1,t} and the effective capacitance of the transmitter 311 gets multiplied up instead of divided down and so is potentially more difficult to accommodate. This arrangement is viable under certain conditions (where sufficient transmit power can be generated and where the transmitter capacitance is small enough that it can still be absorbed), but it is generally less-desirable than the placement at T_{X1}.

FIG. 4 shows the basic construction of a common-gate low-noise amplifier 400 with a trifilar transformer for high gain and impedance matching. For maximum gain, the primary winding T_{1,p} is coupled to the secondary winding T_{1,s} and the primary winding T_{1,p} is also coupled to the tertiary winding T_{1,t}. However, the tertiary winding T_{1,t} is not coupled (or at least only coupled with a low coupling coefficient) to the secondary winding T_{1,s} so as to ensure stability of the amplifier. The turns ratios of T_{1,p} to T_{1,s} and T_{1,p} to T_{1,t} also affect the impedance matching of the amplifier 400 and therefore both the gain and the impedance matching can be set as desired. The three windings T_{1,p}, T_{1,s} and T_{1,t}, together with the field effect transistor M₁ in common-gate arrangement form the impedance matching amplifier. As with the common-source amplifier 200 of FIG. 2, stacked on top of the transistor M₁ and tertiary winding T_{1,t}, are two common-gate stages each comprising a field effect transistor M₂ or M₃ to increase the output impedance. The topmost common-gate stage transistor M₃ improves reverse isolation by providing a high output impedance and thereby isolating the load (represented by inductor L and capacitor C) from the common-source amplifier stage M₁. Note that both common-gate stages M₂ and M₃ are always-ON. These are not arranged to be switchable. The output RFₒ of the amplifier 400 is taken from above the tertiary winding T_{1,t} such that the tertiary winding T_{1,t} lies between the output RFₒ and the drain of M₁.

FIG. 5 shows the common-gate amplifier of FIG. 4 but showing the transmitter 510 connected to the antenna in accordance with embodiments of the invention. Although not shown in FIG. 5, the antenna is connected to the signal path 520 to the right, with a filter interposed between the antenna and the circuit of FIG. 5 as shown in FIG. 1a. The signal path 520 carries the receive signal from the antenna through the filter and into the receiver as indicated by RFᵢ.

As with FIG. 3, the transmitter 510 is directly and continually connected to the signal path 520. There are no switches in the path from the transmitter 510 to the signal path 520 that disconnect the transmitter 510, so it is in an always-connected state. This does not mean that it is always transmitting, but it means that even when the transmitter 510 is not generating a transmit signal, its “off-capacitance” is still present and affects the other components attached to the signal path 520.

The transmitter 510 is powered through the inductor T_{1,q}, which is a quaternary winding of the quadrifilar transformer T₁. As is shown in FIG. 5, the winding T_{1,q} is connected between the supply rail, V_{dd}, and the signal path 520. Therefore, current flows from the supply rail onto the signal path 520 and from there to the transmitter 510 which is in turn connected to ground (not shown). The voltage of the supply rail is not applied to the source of field effect transistor M₁ due to the isolation provided by the windings of the transformer T₁. The AC signals (both transmit and receive) are coupled into the source of M₁ via the mutual coupling of the quaternary winding T_{1,q} with the primary winding T_{1,p}. No DC blocking capacitor is required in this arrangement as the transformer T₁ provides this function. In both FIGS. 4 and 5, the transistor M₁ is biased via the voltage V₁ provided through secondary winding T_{1,s}.

The use of the quaternary winding is advantageous as it allows NMOS transistors to be used in both the amplifier (i.e., M₁, M₂, M₃) and the transmitter 510 (details of which are not shown). NMOS transistors are generally preferred where possible. There is a minor disadvantage to coupling the signal in via the quaternary winding T_{1,q} which is that there will never be a perfect coupling coefficient between the quaternary and primary windings and therefore there will be some signal attenuation. Additionally, the quaternary winding is an extra winding that needs to be formed on the chip and thus could add to the area and/or cost. However, the benefits of using NMOS transistors can outweigh these disadvantages.

As with the arrangement of FIG. 3, the use of the transformer winding T_{1,q} to power the transmitter has the benefit that it allows the signal swing of the transmitter to reach higher than the supply voltage, i.e. it can swing from almost ground up to almost 2*V_{dd}.

In addition, because the transmitter 510 is connected to the signal path 520 adjacent the amplifier 500, its capacitance (i.e., its off-capacitance) can be taken into account in the impedance matching design of the amplifier 500. This arrangement was discussed above and is further set out in WO2019/086853, although that document does not show the quaternary winding T_{1,q}. The trifilar transformer T₁ of the amplifier 500 defines both the input impedance of the amplifier 500 and its gain. The primary winding T_{1,p} is connected to the source of M₁, the secondary winding T_{1,s} is connected to the gate of M₁ and the tertiary winding T_{1,t} is connected to the drain of M₁. The quaternary winding T_{1,q} is coupled to the primary winding T_{1,p} (and is also coupled to the secondary and tertiary windings T_{1,s} and T_{1,t}). The primary winding T_{1,p} and the secondary winding T_{1,s} are coupled in an inverting relationship while the primary winding T_{1,p} and the tertiary winding T_{1,t} are coupled in non-inverting relationship. With the right design of the transformer T₁, there can also be very low or substantially no coupling between the secondary winding T_{1,s} and the tertiary winding T_{1,t}. The coupling between the primary and secondary windings T_{1,p}, T_{1,s} increases the gate-source voltage of M₁, thereby providing one gain mechanism. The coupling between the primary and tertiary windings T_{1,p}, T_{1,t} increases the drain-source current, thereby providing an additional gain mechanism. At the same time, as the input impedance of the arrangement depends upon both the transconductance of the transistor and the turns ratios of the four windings of the transformer T₁, it is possible to achieve good impedance matching via a well-defined input impedance as well as high gain. The capacitance of the transmitter 510 can be taken into account when selecting M₁ and the turns ratios of the windings T_{1,p}, T_{1,s}, T_{1,t} and T_{1,q} so that the amplifier 500 remains properly matched for optimum signal transfer into the amplifier (minimal reflection). As the transmitter 510 is always-connected, the impedance matching of the amplifier 500 does not change between transmit and receive modes and therefore it continues to operate efficiently throughout both transmit and non-transmit operation, thereby allowing good full-duplex (or pseudo-full-duplex) operation.

FIGS. 6a and 6b are similar to FIG. 5 and therefore description of most of the circuits and their operation will be omitted here. The difference is that the transmitter 610 is connected directly to the source of M₁ rather than through a quaternary winding. Thus, the transformer T₁ in FIGS. 6a and 6b is a trifilar transformer and the transmitter 610 is powered through the primary winding T_{1,p}. In FIG. 6a the primary winding T_{1,p} is connected between the signal path 620 and ground and the transmitter 610 is most likely a PMOS-based transmitter. In FIG. 6b the primary winding T_{1,p} is connected between the signal path 620 and the supply rail V_{dd} and the transmitter 610 is most likely an NMOS-based transmitter.

FIG. 7 shows a filter 700 which may be the filter 20 of FIGS. 1a and 1b (and as referenced in relation to the other figures). The filter 700 is an LC-based passive filter comprising three inductors L₁, L₂, L₃ and two capacitors C₁, C₂. The signal path 750 extends between the input, RFᵢ and the output, RFₒ (although it will be appreciated that it is a passive filter and so also functions to filter signals passing in the opposite direction from RFₒ to RFᵢ). FIG. 7 shows three possible placements for the transmitter, labelled as T_{X1} 710, T_{X2} 720 and T_{X3} 730. In each case, the transmitter is powered by one of the inductors of the filter 700 (powered in the sense that it sources and/or sinks current through the inductor). It will be appreciated that only one transmitter is generally required, and that FIG. 7 shows all three possible placements simply by way of illustration (although several transmitters could be employed simultaneously if desired for any reason). Transmitter 710 is sinks/sources current through inductor L₁, transmitter 720 sinks/sources current through inductor L₂ and transmitter 730 sinks/sources current through inductor L₃. Each of the inductors in this example is connected between the supply rail, V_{dd} and the signal path 750 and the transmitter 710, 720 and/or 730 is most likely an NMOS-based transmitter. It will be appreciated that in other examples the inductors L₁, L₂, L₃ could all be connected to ground and the transmitter 710, 720 and/or 730 would most likely be a PMOS-based transmitter. It will of course be appreciated that the principle is not limited to a filter with three inductors but that it can be applied to a filter with any number of inductors and capacitors.

FIG. 8 shows a pulsed (or impulse) radar 800 which comprises a module 860 on which is mounted an antenna 810 and a semiconductor chip 850. The antenna 810 connects to the semiconductor chip 850 via an antenna interface 815. The semiconductor chip 850 contains a filter 820, a transmitter 830 and an amplifier 840 which may be circuits as described above and shown in the preceding figures. In this embodiment the antenna 810, antenna interface 815, filter 820, transmitter 830 and amplifier 840 are all differential. However, a single-ended implementation is also viable by simply implementing one half of the differential circuit.

It will be appreciated that variations and modifications of the above circuits may be made without departing from the scope of the appended claims.

1. A transceiver circuit for transmitting and receiving via a single antenna interface, the transceiver circuit comprising:
a transmitter arranged to send a transmit signal to the antenna interface;
an amplifier arranged to receive a receive signal from the antenna interface; and
a filter arranged between the antenna and the amplifier;
wherein the transmitter circuit is arranged to source and/or sink current through an inductive element and wherein the inductive element is part of either the filter or the amplifier.

2. A transceiver circuit as claimed in claim 1, wherein the inductive element is connected to a supply rail or to ground.

3. A transceiver circuit as claimed in claim 1, wherein the amplifier is an impedance matching amplifier and wherein the inductive element is part of a transformer of the amplifier.

4. A transceiver circuit as claimed in claim 1, wherein the amplifier comprises an impedance matching amplifier arranged to receive the receive signal from the antenna interface.

5. A transceiver circuit as claimed in claim 4, wherein the impedance matching amplifier comprises a transistor or multiple transistors arranged in a common-gate and/or a common-source arrangement.

6. A transceiver circuit as claimed in claim 5, wherein the transceiver circuit further comprises a DC blocking capacitor between the inductive element and the control terminal of the transistor.

7. A transceiver circuit as claimed in claim 5, wherein the impedance matching amplifier comprises a field effect transistor and wherein the impedance matching amplifier further comprises a transformer coupling the signal between the gate and the source of the field effect transistor.

8. A transceiver as claimed in claim 7, wherein the inductive element is a winding of the transformer.

9. A transceiver circuit as claimed in claim 7, wherein the field effect transistor is in common-source arrangement and the amplifier comprises a transformer arranged to amplify the signal at the gate of the field effect transistor.

10. A transceiver circuit is claimed in claim 9, wherein the transformer is a trifilar transformer with a primary winding connected to the source, a secondary winding connected between the gate and ground and a tertiary winding connected between the secondary winding and the gate, wherein the primary winding and the secondary winding are coupled in inverting relationship, wherein the secondary winding and the tertiary winding are coupled to increase voltage at the gate, and wherein there is substantially no coupling between the primary winding and the tertiary winding.

11. A transceiver circuit as claimed in claim 7, wherein the field effect transistor is in common-gate arrangement and comprises a transformer coupling the signal between the source and the drain of the field effect transistor.

12. A transceiver circuit as claimed in claim 11, wherein the transformer is a trifilar transformer with a primary winding connected to the source, a secondary winding connected to the gate and a tertiary winding connected to the drain, wherein the primary winding and the secondary winding are coupled in an inverting relationship and wherein the primary winding and the tertiary winding are coupled in non-inverting relationship, and wherein there is substantially no coupling between the secondary winding and the tertiary winding.

13. A transceiver circuit as claimed in claim 1, wherein the transmitter is arranged to remain in signal communication with the amplifier during both transmit operation and non-transmit operation.

14. A transceiver circuit as claimed in claim 13, wherein there is no switch between the transmitter and the amplifier.

15. A transceiver circuit as claimed in claim 1, wherein the amplifier is arranged to remain in signal communication with the antenna during both transmit operation and non-transmit operation.

16. A transceiver circuit as claimed in claim 17, wherein there is no switch between the antenna and the amplifier.

17. A transceiver circuit as claimed in claim 1, wherein the transmitter, amplifier and filter are all fabricated on the same chip.

18. A transceiver circuit as claimed in claim 1, wherein the transmitter is connected to a node between the filter and the amplifier.

19. A transceiver circuit for transmitting and receiving via a single antenna interface, the transceiver circuit comprising:
a transmitter arranged to send a transmit signal to the antenna interface;
an amplifier arranged to receive a receive signal from the antenna interface; and
a filter arranged between the antenna and the amplifier;
wherein the transmitter is connected to a node between the filter and the amplifier.

20. A transceiver comprising:
an antenna; and
a transceiver circuit as claimed in claim 19.

21. A transceiver as claimed in claim 20, wherein the transmitter comprises an impulse or pulse generator.

22. A pulsed radar comprising a transceiver as claimed in claim 21.

23. A method of duplex operation of a transceiver circuit via a single antenna interface, wherein the transceiver circuit comprises:
a transmitter arranged to send a transmit signal to the antenna interface; and
an amplifier arranged to receive a receive signal from the antenna interface; and
a filter arranged between the antenna and the amplifier;
wherein the method comprises:
the transmitter transmitting a transmit signal by sourcing and/or sinking current through an inductive element.

24. A method of duplex operation of a transceiver circuit via a single antenna interface, wherein the transceiver circuit comprises:
a transmitter arranged to send a transmit signal to the antenna interface; and
an amplifier arranged to receive a receive signal from the antenna interface; and
a filter arranged between the antenna and the amplifier;
wherein the method comprises:
the transmitter transmitting a transmit signal onto a node between the filter and the amplifier.
